(19) United States
(12) Patent Application Publication
(10) Pub. No.: US 2006/0112730 A1
(43) Pub. Date: Jun. 1, 2006

(54) Core insert for a glass molding machine, and an apparatus for making the same

(75) Inventor: Ga-Lane Chen, Fremont, CA (US)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Chen City (TW)

(21) Appl. No.: 11/228,881

(22) Filed: Sep. 16, 2005

(30) Foreign Application Priority Data
Nov. 26, 2004 (CN) 200410052544.9

(51) Int. Cl. C03B 11/08; C23C 14/00

(52) U.S. Cl. 65/374.11; 204/298.01

(57) ABSTRACT

A core insert (1) for glass molding machine includes a substrate (10) and a plurality of complex films (12) deposited on a surface of the substrate (10). Each complex film (12) is composed of a noble metal layer (120), an insulating metal oxide layer (122), and a hard film (124). The insulating metal oxide layer is formed on a surface of the noble metal layer, and the hard film is formed on a surface of the insulating metal oxide layer. A vacuum sputtering apparatus 2 for making a core insert includes a vacuum chamber 4, a plurality of target frameworks for holding a plurality of targets, and a substrate framework for holding substrates. The target frameworks and the substrate framework are installed in the vacuum chamber, and the substrate framework has a rotation mechanism and a revolution mechanism associated therewith.

### BACKGROUND OF THE INVENTION

1. Field of the Invention

The present invention generally relates to glass molding machines and, more particularly, to a core insert for a glass molding machine.

2. Discussion of the Related Art

Currently, digital camera modules are included as a feature in a wide variety of portable electronic devices. Most portable electronic devices are becoming progressively more miniaturized over time, and digital camera modules are correspondingly becoming smaller and smaller. Nevertheless, in spite of the small size of a contemporary digital camera module, consumers still demand excellent imaging. Image quality of a digital camera is mainly dependent upon the optical elements of the digital camera module.

Aspheric lenses are very important elements in the digital camera module. Contemporary aspheric lenses are manufactured by way of glass molding. The glass molding machine operates at a high temperature and high pressure during the glass molding process. Therefore, core inserts are needed and must be accurately designed and manufactured. The core inserts should have excellent chemical stability in order not to react with the glass material. In addition, the core inserts also should have sufficient rigidity, a suitable hardness, and excellent mechanical strength in order not to be scratched. Furthermore, the core inserts should be impact-resistant at high temperatures and high pressures. Moreover, the core inserts must have excellent machinability, in order for them to be machined precisely and easily to form the desired optical surfaces. Finally, the core inserts must have a long working lifetime so that the cost of manufacturing aspheric lenses is reduced.

A typical contemporary core insert includes a substrate and a protective film. The substrate is made of stainless steel, carborundum (SiC), or tungsten carbide (WC). The protective film is made of diamond-like carbon film (DLC), noble metals, or alloys of noble metals. The noble metals can be platinum (Pt), iridium (Ir) or ruthenium (Ru). The alloys of noble metals can be iridium-ruthenium (Ir—Ru), platinum-iridium (Pt—Ir), or iridium-rhenium (Ir—Re). The diamond-like carbon film generally has a short working lifetime. The noble metals or alloys of noble metals have good chemical stability, rigidity and heat-resistance. Nevertheless, the protective film made of noble metals or alloys of noble metals tends to have poor adhesion with the substrate. Thus, the core insert, as a whole, generally has a short working lifetime, which escalates the cost of producing aspheric lenses.

Therefore, a core insert for a glass molding machine which overcomes the above-described problems is desired.

### SUMMARY OF THE INVENTION

A core insert for a glass molding machine includes a substrate and a complex film deposited on a surface of the substrate. The complex film includes a noble metal layer, an insulating metal oxide layer, and a hard film. The insulating metal oxide layer is formed on a surface of the noble metal layer, and the hard film is formed on a surface of the insulating metal oxide layer.

A vacuum sputtering apparatus for making a core insert includes a vacuum chamber, a plurality of target frameworks for respectively holding a plurality of targets, and a substrate framework for holding a substrate. The target frameworks and the substrate framework are installed in the vacuum chamber, and the substrate framework has a rotation mechanism and a revolution mechanism.

Other objects, advantages and novel features will become more apparent from the following detailed description when taken in conjunction with the accompanying drawings.

### BRIEF DESCRIPTION OF THE DRAWINGS

Many aspects of the core insert and the vacuum sputtering apparatus can be better understood with reference to the following drawings. The components in the drawings are not necessarily to scale, the emphasis instead being placed upon clearly illustrating the principles of the present core insert and vacuum sputtering apparatus. Moreover, in the drawings, like reference numerals designate corresponding parts throughout the several views.

FIG. 1 is a cross-sectional view of a core insert in accordance with a preferred embodiment of the present insert;

FIG. 2 is a schematic view of a vacuum sputtering apparatus in accordance with a preferred embodiment of the present apparatus for making a core insert;

FIG. 3 is a cross-sectional view of the vacuum sputtering apparatus taken along line III-III in FIG. 2;

FIG. 4 is a cross-sectional view of the vacuum sputtering apparatus taken along line IV-IV in FIG. 2;

FIG. 5 is a cross-sectional view of the permanent magnets of the vacuum sputtering apparatus in FIG. 3; and

FIG. 6 is a schematic view of the RF circuitry of the vacuum sputtering apparatus in FIG. 3.

### DETAILED DESCRIPTION OF THE EMBODIMENT

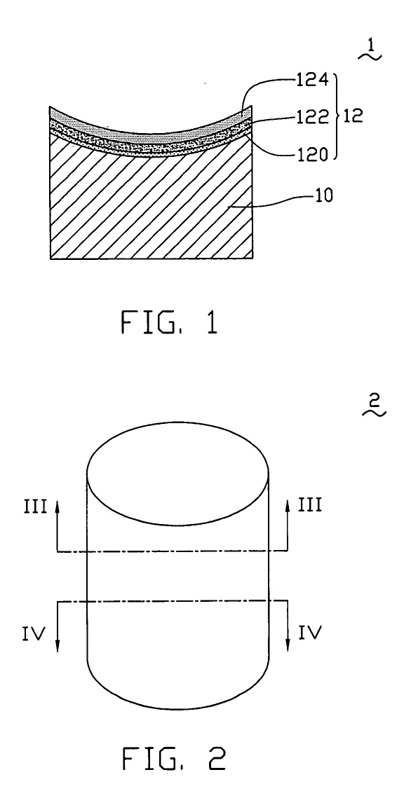

Referring to FIG. 1, in a preferred embodiment, a core insert 1 includes a substrate 10 and at least one complex film 12 (for simplicity, only one such film 12 being shown). The substrate 10 is, advantageously, made of carborundum (SiC), tungsten carbide (WC), or a mixture/composite thereof. Each complex film 12 includes a noble metal layer 120, an insulating metal oxide layer 122, and a hard film 124. The insulating metal oxide layer 122 is formed on a surface of the noble metal layer 120, and the hard film 124 is formed on a surface of the insulating metal oxide layer 122. It is to be understood that each complex film 12 may have a same or different overall composition relative to any other complex film 12, in accordance with the properties desired for core insert 1.

For achieving a long working lifetime, an appropriate number of complex films 12 advantageously is approximately in the range of 1-30, preferably about in the range of 5-10. The noble metal layer 120 is usefully made of a material selected from the group consisting of platinum (Pt), iridium (Ir), ruthenium (Ru), and any combination thereof. The noble metal layer 120 has a preferred thickness in the approximate range of 3-10 angstrom. The insulating metal oxide layer 122 is advantageously made of a material selected from the group consisting of ZrO₂—xY₂O₃, ZrO₂—xY₂O₃—yAl₂O₃, and Al₂O₃. The x is a proportion by weight about in the range of 3-15%, and the y is a proportion by weight in the general range of 3-5%. The insulating metal oxide layer has a preferred thickness in the approximate range of 40-80 angstrom. The hard film is usefully made of at least one material selected from the group consisting of diamond-like carbon film (DLC), silicon nitride (Si₃N₄), cubic boron nitride (cBN), tungsten carbide (WC), and boron nitride carbide (BCN), and the hard film has a preferred thickness in the general range of 40-80 angstrom.

Referring to FIGS. 2-4, in a preferred embodiment of the present apparatus, a vacuum sputtering apparatus 2 for making the core insert 1 includes a vacuum chamber 4, a target holding mechanism 22, and a substrate framework part 242 for holding substrates 10. The target holding mechanism 22 and the substrate framework 242 are installed in separate sides of the vacuum chamber 4. The substrate framework 242 has a rotation mechanism 202 (schematically shown) and a revolution mechanism 204 (schematically shown) for controlling the substrate framework 242 rotating and revolving, respectively.

The target holding mechanism 22 includes a first target framework 221, a second framework 222, and a third framework 223. The first target framework 221 holds or carries a first target 31 made of a material selected from the group consisting of platinum (Pt), iridium (Ir), ruthenium (Ru), and any combination thereof. Because of the high cost of the first target material 31, the first target 31 has a smaller diameter about in the range of 1-2 inch. The first target 31 is electrically connected to an AC power supply 51 (schematically shown), and the AC power supply 51 has a frequency in the approximate range of 150-500 kilohertz.

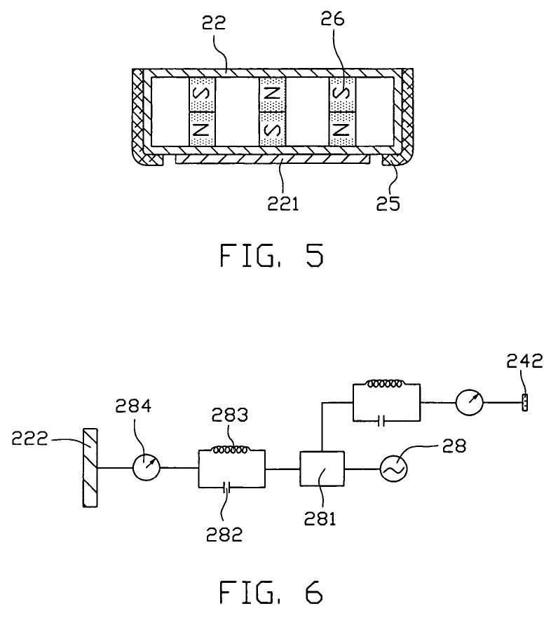

The second framework 222 holds/carries a second target 32 made of a material selected from the group consisting of ZrO₂—xY₂O₃, ZrO₂—xY₂O₃—yAl₂O₃, and Al₂O₃. The second target 32 has a diameter approximately in the range of 4-8 inch. The second target 32 is electrically connected a RF (radio frequency) power supply 28 (FIG. 6), and the RF power supply 28 advantageously has a frequency of about 13.56 megahertz.

The third framework 223 holds/carries a third target 33 advantageously made of a material selected from the group consisting of diamond-like carbon film (DLC), silicon nitride (Si₃N₄), cubic boron nitride (cBN), tungsten carbide (WC), and boron nitride carbide (BCN). The third target 33 has a diameter about in the range of 4-8 inch. The third target 33 is electrically connected a DC power supply 52 (schematically shown), and the DC power supply 52 usefully has a power in the general range of 200-1000 watt. Some gas inlets 27 are formed around each target frameworks and are configured for introducing sputtering gas or inert gas.

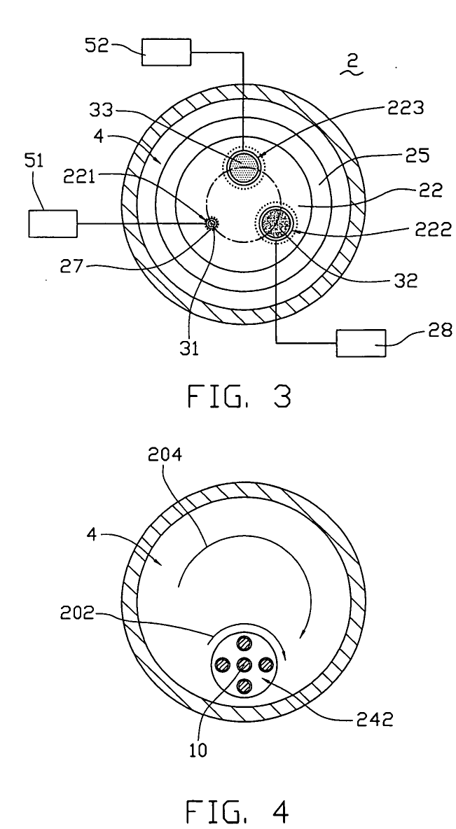

Referring to FIGS. 3 and 6, the RF power supply 28 transfers power to the second target 32, via the second target framework 222, and a substrate 10, via the substrate framework 242, through a common exciter 281, a capacitor 282, a inductor 283, and a voltage meter 284. Eighty to ninety-eight percent of the RF power is transferred to the second target 32, and two to twenty percent of RF power is transferred to the substrate 10.

Referring to FIG. 5, a permanent magnetic 26 is installed on the back of the first target framework 221 for accelerating the rate of sputtering. The second target framework 222 and the third target 223, advantageously, are also attached to the permanent magnetic 26. (It is considered to be within the scope of the invention for any or all of target frameworks 221-223 to be attached to the permanent magnet 26 and/or placed in the field thereof.) The permanent magnetic 26 is usefully made of a material selected from the group consisting of NdFeB (neodymium-iron-boron), SrₓBa_{y}Fe_{z}Oₙ (Strontium-barium-iron-oxide), and NiCrCo (nickel-chromium-cobalt). Each target framework 221-223 is grounded and/or covered by a shielding cover 25 configured for reducing and/or preventing electromagnetic interference.

Referring to FIGS. 1-4, a method for making a core insert 1 using the vacuum sputtering apparatus 2 includes the steps of:

(1) mounting a substrate 10 on the substrate framework 242;

(2) installing a first target 31 on the first target framework 221, the first target 31 being made of a material selected from the group consisting of platinum (Pt), iridium (Ir), ruthenium (Ru), and any combination thereof;

(3) installing a second target 32 on the second framework 222, the second target 32 being made of a material selected from the group consisting of ZrO₂—xY₂O₃, ZrO₂—xY₂O₃—yAl₂O₃, and Al₂O₃;

(4) installing a third target 33 on the third framework 223, the third target 33 being made of at least one material selected from the group consisting of diamond-like carbon film (DLC), silicon nitride (Si₃N₄), cubic boron nitride (cBN), tungsten carbide (WC), and boron nitride carbide (BCN);

(5) evacuating the vacuum chamber until an approximate pressure therein is 0.1-1 Pa;

(6) depositing a noble metal layer 120 on a surface of the substrate 10 by using the first target 31 and the AC power supply 51, then depositing an insulating metal oxide layer 122 on a surface of the noble metal layer 120 by using the second target 32 and the RF power supply 28, and depositing a hard film 124 on a surface of the insulating metal oxide layer 122 by using the third target 33 and the DC power supply 52, the noble metal layer 120, the insulating metal oxide layer 122, and the hard film 124 together forming a complex film 12;

(7) continuing to deposit a predetermined layer number of complex films 12; and

(8) obtaining a core insert 1 for glass molding machine.

The core insert 1 according to a preferred embodiment is composed of a plurality of complex films 12, which can be operated at a high temperature and high pressure and thereby contribute to a long working lifetime. The vacuum sputtering apparatus 2, according to a preferred embodiment, can employ a plurality of targets (i.e., 31, 32, and 33) in one sputtering process. Thus, various coatings (i.e., a chosen number of complex films 12) can be obtained in one sputtering process without opening the vacuum chamber 4 of the sputtering apparatus 2.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A core insert for a glass molding machine, comprising:
a substrate; and
a plurality of complex films deposited on a surface of the substrate, each complex film comprising a noble metal layer, an insulating metal oxide layer, and a hard film, the insulating metal oxide layer being formed on a surface of the noble metal layer, and the hard film being formed on a surface of the insulating metal oxide layer.

2. The core insert as claimed in claim 1, wherein the complex films number about in the range of 5-10.

3. The core insert as claimed in claim 1, wherein the noble metal layer of each complex film is made of a material selected from the group consisting of platinum, iridium, ruthenium, and any combination thereof, the noble metal layer having a thickness in the approximate range of 3-10 angstrom.

4. The core insert as claimed in claim 1, wherein the insulating metal oxide layer of each complex film is made of a material selected from the group consisting of ZrO₂—xY₂O₃, ZrO₂—xY₂O₃—yAl₂O₃, and Al₂O₃, the insulating metal oxide layer having an approximate thickness in the range of 40-80 angstrom.

5. The core insert as claimed in claim 4, wherein x and y are proportions by weight, x being about in the range of 3-15%, y being about in the range of 3-5%.

6. The core insert as claimed in claim 1, wherein the hard film of each complex film is made of at least one material selected from the group consisting of diamond-like carbon film (DLC), silicon nitride (Si₃N₄), cubic boron nitride (cBN), tungsten carbide (WC), and boron nitride carbide (BCN), the hard film having a thickness about in the range of 40-80 angstrom.

7. A vacuum sputtering apparatus for making a core insert, comprising:
a vacuum chamber;
a target holding mechanism installed in the vacuum chamber, the target holding mechanism holding a plurality of targets; and
a substrate framework positioned in the vacuum chamber, the substrate framework holding a plurality of substrates, the substrate framework having a rotation mechanism and a revolution mechanism associated therewith.

8. The vacuum sputtering apparatus as claimed in claim 7, wherein the target holding mechanism comprises a first target framework, a second target framework, and a third target framework.

9. The vacuum sputtering apparatus as claimed in claim 8, wherein the first target framework holds a first target comprised of a material selected from the group consisting of platinum, iridium, ruthenium, and any combination thereof, the first target having a diameter about in the range of 1-2 inch.

10. The vacuum sputtering apparatus as claimed in claim 9, wherein the first target is electrically connected to an AC power supply, and the AC power supply has an approximate frequency in the range of 150-500 Kilohertz.

11. The vacuum sputtering apparatus as claimed in claim 8, wherein the second target framework holds a second target comprised of a material selected from the group consisting of ZrO₂—xY₂O₃, ZrO₂—xY₂O₃—yAl₂O₃, and Al₂O₃, the second target having a diameter about in the range of 4-8 inch.

12. The vacuum sputtering apparatus as claimed in claim 11, wherein the second target is electrically connected to a RF (radio frequency) power supply.

13. The vacuum sputtering apparatus as claimed in claim 12, wherein the RF power supply has a frequency of about 13.56 Megahertz.

14. The vacuum sputtering apparatus as claimed in claim 8, wherein the third target framework holds a target comprised of a material selected from the group consisting of diamond-like carbon film (DLC), silicon nitride (Si₃N₄), cubic boron nitride (cBN), tungsten carbide (WC), and boron nitride carbide (BCN), the target having a diameter in the range of 4-8 inch.

15. The vacuum sputtering apparatus as claimed in claim 14, wherein the target is electrically connected a DC power supply, and the DC power supply has a power in the approximate range of 200-1000 watt.

16. The vacuum sputtering apparatus as claimed in claim 7, wherein at least one of the group consisting of the target frameworks and the substrate framework are in a magnetic field of a permanent magnet.

17. The vacuum sputtering apparatus as claimed in claim 16, wherein the target frameworks and the substrate framework each are in the magnetic field of the permanent magnet.
